(19) United States
(12) Patent Application Publication
(10) Pub. No.: US 2026/0269590 A1
(43) Pub. Date: Sep. 10, 2026

(54) WIRING HARNESS AND WIRE FIXATION MEMBER

(71) Applicant: SUMITOMO WIRING SYSTEMS, LTD., Yokkaichi-shi, Mie (JP)

(72) Inventor: Tomohiro YABASHI, Yokkaichi-shi (JP)

(73) Assignee: SUMITOMO WIRING SYSTEMS, LTD., Yokkaichi-shi, Mie (JP)

(21) Appl. No.: 19/166,349

(22) PCT Filed: Mar. 5, 2024
(86) PCT No.: PCT/JP2024/008197

§ 371 Date: Sep. 17, 2025

(30) Foreign Application Priority Data
Mar. 22, 2023 (JP) 2023-045553

(51) Int. Cl. H02G 3/32; H02G 3/04

(52) U.S. Cl. CPC H02G 3/32; H02G 3/0468

(57) ABSTRACT

A wiring harness including: a wire member that includes: an exterior tube; and a wire that passes through an inside of the exterior tube; a wire fixation member configured to fix the wire member with a fixing part; and a ring-shaped magnetic core that surrounds an outer periphery of the exterior tube, wherein: the wire fixation member includes a fixation part that is fixed by the fixing part; a wire holding part that holds the wire member; and a core holding part that holds the magnetic core, the wire holding part and the core holding part are juxtaposed in a length direction of the wire member.

### BACKGROUND

The present disclosure relates to a wiring harness and a wire fixation member.

A wiring harness described in JP 2015-154040A, for example, includes a wire fixation member for fixing a wire member to a support base of a vehicle and a magnetic core held by the wire fixation member. The wire member has an exterior member such as a corrugated tube and wires that pass through the inside of the exterior member. The wire fixation member has a ring-shaped wire holding part that holds the exterior member of the wire member. The magnetic core has a ring shape that surrounds the outer periphery of the exterior member. The wire fixation member holds the magnetic core with the wire holding part. The magnetic core consists of a ferrite core, for example. The magnetic core is capable of absorbing electromagnetic noise emitted by the wires.

### SUMMARY

In a wiring harness such as described above, the magnetic core is disposed on the inner peripheral side of the wire holding part, thus giving rise to concern about the wire fixation member increasing in size in the radial direction of the wire member.

An exemplary aspect of the disclosure provides a wiring harness and a wire fixation member that enable a magnetic core to be provided while suppressing an increase in size.

A wiring harness of the present disclosure including a wire member including a tubular exterior member and a wire passing through an inside of the exterior member, a wire fixation member configured to fix the wire member with a fixing part, and a ring-shaped magnetic core surrounding an outer periphery of the exterior member, the wire fixation member including a fixation part that is fixed by the fixing part, a wire holding part that holds the wire member, and a core holding part that holds the magnetic core, and the wire holding part and the core holding part being juxtaposed in a length direction of the wire member.

According to a wiring harness and a wire fixation member of the present disclosure, a magnetic core can be provided while suppressing an increase in size.

### BRIEF DESCRIPTION OF THE DRAWINGS

FIG. 1 is a perspective view of a wiring harness in an embodiment.

FIG. 2 is a plan view of the wiring harness in the embodiment.

FIG. 3 is a cross-sectional view taken along line 3-3 in FIG. 2.

FIG. 4 is a front view of the wiring harness in the embodiment.

FIG. 5 is a perspective view from above of a wire fixation member in the embodiment.

FIG. 6 is a perspective view from below of the wire fixation member in the embodiment.

FIG. 7 is a front view of a wiring harness in a modification.

### DETAILED DESCRIPTION OF EMBODIMENTS

Initially, modes of the present disclosure will be enumerated and described.

A wiring harness of the present disclosure is:

[1]A wiring harness of the present disclosure including a wire member including a tubular exterior member and a wire passing through an inside of the exterior member, a wire fixation member configured to fix the wire member with a fixing part, and a ring-shaped magnetic core surrounding an outer periphery of the exterior member, the wire fixation member including a fixation part that is fixed by the fixing part, a wire holding part that holds the wire member, and a core holding part that holds the magnetic core, and the wire holding part and the core holding part being juxtaposed in a length direction of the wire member.

According to this configuration, it becomes possible to suppress an increase in size of the wire fixation member in the radial direction of the wire member, compared with a configuration in which the magnetic core is disposed on the inner peripheral side of the wire holding part. Accordingly, it becomes possible to suppress an increase in size in the radial direction in the region where the magnetic core is provided in the wiring harness.

[2] In [1] above, the core holding part includes a core holding part main body formed integrally with the wire holding part, and a fastening member that fastens and fixes the magnetic core to the core holding part main body.

According to this configuration, it becomes possible to securely hold the magnetic core with the core holding part main body and the fastening member.

[3] In [2] above, the core holding part main body holds a range from 90 degrees to 180 degrees inclusive of the magnetic core in a circumferential direction thereof.

According to this configuration, it becomes possible to stably hold the magnetic core with the core holding part main body.

[4] In any of the above [1] to [3] above, the wire fixation member has a coupling part joining the wire holding part to the core holding part, and the coupling part has a reinforcing rib.

According to this configuration, it becomes possible to improve the rigidity of the wire fixation member from the wire holding part to the core holding part with the reinforcing rib.

[5] In any of the above [1] to [4] above, the magnetic core is formed in a ring shape by a single component.

According to this configuration, the magnetic core is formed from a single component, thus contributing to improving the capacity of the magnetic core to absorb electromagnetic noise.

[6] In any of the above [1] to [4] above, the magnetic core is formed in a ring shape by a plurality of components.

According to this configuration, it becomes possible to assemble the magnetic core from the outer peripheral side of the wire member. Accordingly, constraints on the order in which the magnetic core is assembled are reduced, and it thus becomes possible to improve the operability with which the magnetic core is assembled.

[7] A wire fixation member of the present disclosure configured to fix a wire member having a tubular exterior member and a wire passing through an inside of the exterior member with a fixing part, including a fixation part that is fixed by the fixing part, a wire holding part that holds the wire member, and a core holding part that holds a ring-shaped magnetic core surrounding an outer periphery of the exterior member, the wire holding part and the core holding part being juxtaposed in a length direction of the wire member.

According to this configuration, it becomes possible to suppress an increase in size of the wire fixation member in the radial direction of the wire member, compared with a configuration in which the magnetic core is disposed on the inner peripheral side of the wire holding part. Accordingly, it becomes possible to suppress an increase in size in the radial direction in the region where the magnetic core is provided.

### DETAILED DESCRIPTION OF EMBODIMENTS OF DISCLOSURE

Specific examples of a wiring harness and a wire fixation member of the present disclosure will be described below with reference to the drawings. In the drawings, some parts of the configuration may be shown in an exaggerated or simplified manner for convenience of description. Also, the dimensional proportions of various portions may differ between the drawings.

Note that “tubular” as used in the description herein includes not only a shape whose peripheral wall is formed continuously around the entire periphery in the circumferential direction, but also a shape in which a plurality of components are combined in a tubular shape, and a shape that is partially cut out or the like in the circumferential direction such as a C-shape. Also, “tubular” shape includes circular, elliptical, and polygonal with pointed or rounded corners.

Also, the term “ring-shaped” as used in the description herein may refer to any structure that forms a loop, or structures having a continuous shape without ends as well as a general loop shape with a gap such as a C-shape. Note that “ring-shaped” shape includes, but is not limited to, circular, elliptical, and polygonal with pointed or rounded corners.

### Wiring Harness 10

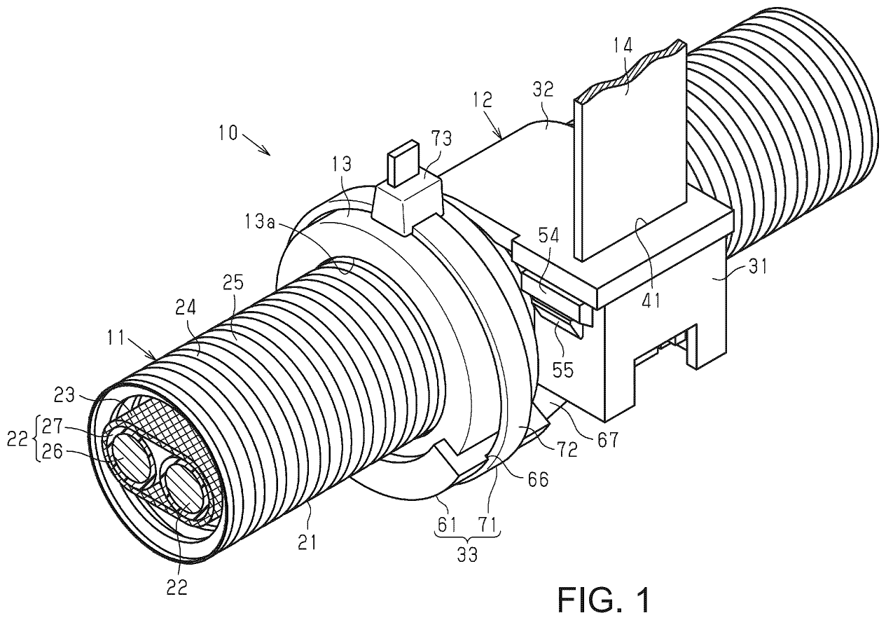

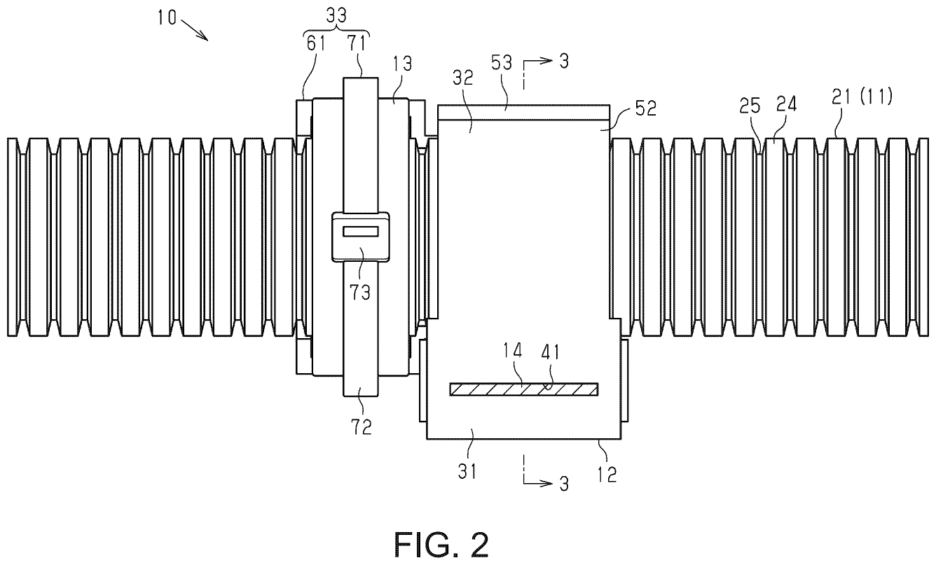

A wiring harness 10 of the present embodiment shown in FIGS. 1 and 2 is provided in a vehicle such as a car, for example. The wiring harness 10 includes a wire member 11, a wire fixation member 12, and a magnetic core 13. The wire fixation member 12 is a component that is fixed by a plate-shaped fixing part 14 provided in the vehicle. The fixing part 14 is, for example, a metal plate-shaped bracket. The wire member 11 electrically connects two or more onboard devices.

### Wire Member 11

As shown in FIG. 1, the wire member 11 has a tubular exterior member 21 (exterior tube) and one or more wires 22 passing through the inside of the exterior member 21. The wire member 11 of the present embodiment has, for example, two wires 22. Also, the wire member 11 has, for example, a braided member 23 that collectively covers the outer periphery of the wires 22. The braided member 23 is provided inside the exterior member 21.

### Exterior Member 21

The exterior member 21 has, for example, a cylindrical shape that covers the outer periphery of the wires 22 and the braided member 23 entirely around in the circumferential direction. The exterior member 21 is sealed entirely around in the circumferential direction. The exterior member 21 of the present embodiment is, for example, a corrugated tube having a bellows structure in which a ring-shaped raised part 24 and a ring-shaped recessed part 25 are alternately connected in the length direction thereof. The exterior member 21 has flexibility. As the material of the exterior member 21, for example, a conductive resin material or a non-conductive resin material can be used. As the resin material, for example, a synthetic resin such as polyolefin, polyamide, polyester, or ABS resin can be used.

### Wires 22

The wires 22 are coated wires each having a core wire 26 formed from a conductor and an insulating coating 27 that covers the outer periphery of the core wire 26.

As the core wire 26, for example, a stranded wire formed by combining a plurality of metal strands, a columnar conductor formed from a single columnar metal rod having a solid structure internally, or a tubular conductor having a hollow structure internally can be used. Also, as the core wire 26, for example, a combination of different types of conductors such as a stranded wire, a columnar conductor, and a tubular conductor can be used. Examples of the columnar conductor include a single-core wire and a busbar. The core wire 26 of the present embodiment is, for example, a stranded wire. As the material of the core wire 26, for example, a metal material such as a copper-based or aluminum-based material can be used.

The cross-sectional shape of the core wire 26 orthogonal to the length direction thereof can be any shape. The cross-sectional shape of the core wire 26 is, for example, formed into a circular shape, a semicircular shape, a polygonal shape, a square shape, a flattened shape, and the like. The cross-sectional shape of the core wire 26 of the present embodiment is formed into a circular shape, for example.

Herein, “flattened shape” includes, for example, rectangular, oblong, and elliptical. Also, herein, “rectangular” is a shape having a long side and a short side and does not include a square. Also, herein “rectangular” includes a shape in which the edge portion is chamfered and a shape in which the edge portion is rounded. Herein, “oblong” is a shape consisting of two parallel lines of substantially equal length and two semicircles.

The insulating coating 27 covers, for example, the outer peripheral surface of the core wire 26 entirely. The insulating coating 27 is, for example, formed from an insulating material such as a synthetic resin. As the material of the insulating coating 27, for example, a synthetic resin whose main component is a polyolefin-based resin such as cross-linked polyethylene or cross-linked polypropylene can be used. Also, as the material of the insulating coating 27, one type of material may be used alone, or two or more types of material may be used in combination as appropriate.

### Braided Member 23

The braided member 23 has, for example, a tubular shape that collectively covers the outer periphery of the wires 22 as a whole. The braided member 23 is, for example, provided so as to cover the outer periphery of the wires 22 over substantially the entirety of the wires 22 in the length direction thereof. As the braided member 23, a braided wire in which a plurality of metal strands are braided together or a braided wire in which metal and resin strands are braided together in combination can be used. As the material of the metal strands, for example, a metal material such as a copper-based or aluminum-based material can be used. As the resin strands, for example, a reinforced fiber having excellent insulation and shear resistance properties such as a para-aramid fiber can be used. Although not illustrated, the braided member 23 is grounded.

### Magnetic Core 13

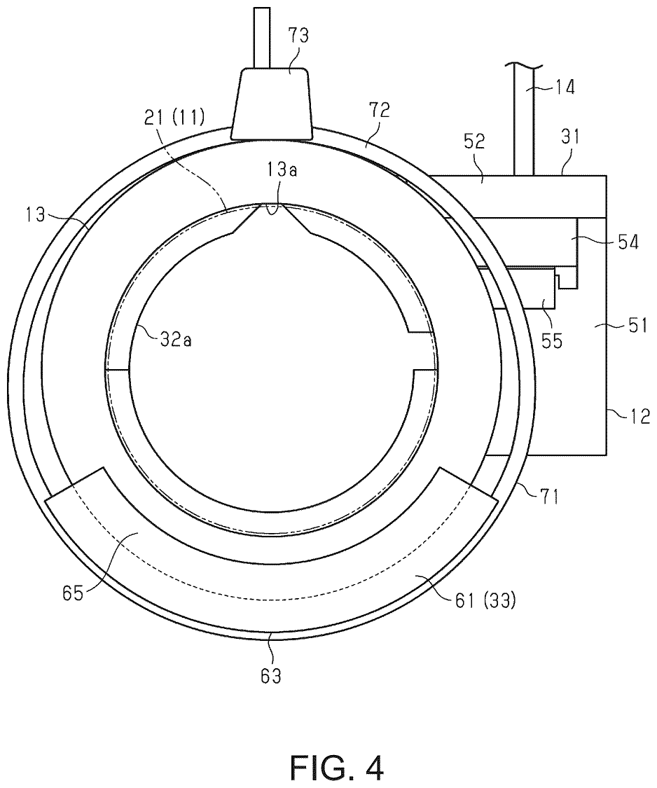

As shown in FIGS. 1 and 4, the magnetic core 13 has a ring shape that surrounds the outer periphery of the exterior member 21. That is, the wire member 11 including the exterior member 21 and the wires 22 passes through the magnetic core 13. The magnetic core 13 of the present embodiment is, for example, formed in a circular ring shape. Note that the “ring shape” of the magnetic core 13 need only be regarded as a ring as a whole, and includes a shape that is partially cut out or the like such as a C-shape. The magnetic core 13 has a through hole 13a through which the wire member 11 passes. The magnetic core 13 is formed in a ring shape having a predetermined length extending in a passthrough direction of the through hole 13a.

The magnetic core 13 is, for example, formed in a ring shape by a single component. Thus, the magnetic core 13 is formed in a closed ring shape that is continuously formed entirely around in the circumferential direction. That is, a slit extending in the length direction of the wire member 11 is not formed in the magnetic core 13.

The magnetic core 13 is, for example, disposed so as to oppose the wire member 11 entirely around in the circumferential direction of the wire member 11. The magnetic core 13 thereby has a function of reducing electromagnetic noise emitted by the wires 22. The magnetic core 13 absorbs electromagnetic waves emitted by the wires 22 and converts the energy of the electromagnetic waves into thermal energy, for example. The adverse effect of electromagnetic waves emitted by the wires 22 on peripheral devices and the like is thereby reduced.

Note that the term “oppose” herein refers to surfaces or members being located in front of each other, and includes not only the case where the surfaces or members are located perfectly in front of each other, but also the case where the surfaces or members are located partially in front of each other. Also, the term “oppose” herein includes both the case where a member separate from two portions is interposed between the two portions and the case where nothing is interposed between the two portions.

The magnetic core 13 is, for example, a molded body containing a soft magnetic material. Examples of the soft magnetic material include iron (Fe), iron alloy, ferrite, and the like. Examples of the iron alloy include Fe-silicon (Si) alloy and Fe-nickel (Ni) alloy. As the magnetic core 13, for example, a ferrite core, an amorphous core, and a permalloy core can be used. The ferrite core consists of, for example, soft ferrite that exhibits soft magnetism. Examples of the soft ferrite include ferrite containing nickel (Ni) and zinc (Zn) and ferrite containing manganese (Mn) and zinc (Zn). The material of the magnetic core 13 can, for example, be selected as appropriate according to the frequency band of electromagnetic noise to be reduced.

### Wire Fixation Member 12

As shown in FIG. 1, the wire fixation member 12 is a component that fixes the wire member 11 with the fixing part 14. The wire fixation member 12 has a fixation part 31 that is fixed by the fixing part 14, a wire holding part 32 that holds the wire member 11, and a core holding part 33 that holds the magnetic core 13. The wire fixation member 12 is formed of, for example, a synthetic resin. The wire holding part 32 and the core holding part 33 are juxtaposed in the length direction of the wire member 11. That is, the core holding part 33 is provided at a position shifted in the length direction of the wire member 11 with respect to the wire holding part 32.

### Fixation Part 31

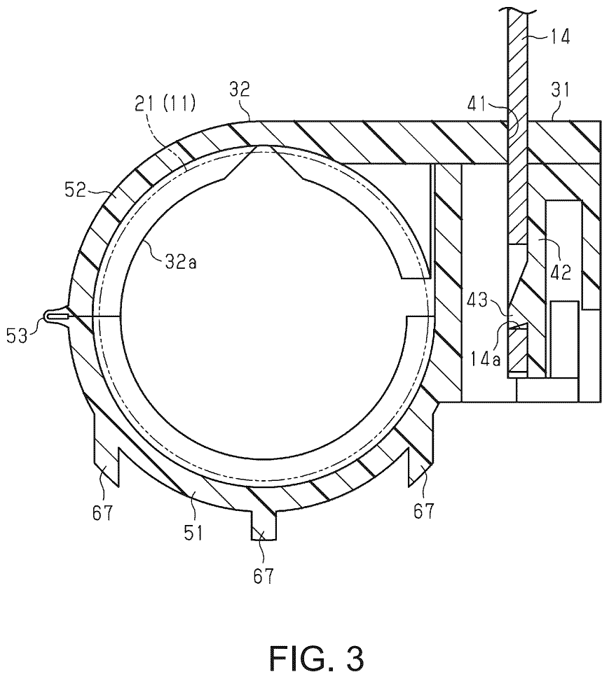

As shown in FIG. 3, the fixation part 31 has, for example, an insertion hole 41 into which the fixing part 14 is inserted and an elastic piece 42 that is located inside the insertion hole 41. A locking protruding part 43 provided on the elastic piece 42 catches in a locking hole 14a formed in the fixing part 14. The fixing part 14 is thereby prevented from coming out of the insertion hole 41.

### Wire Holding Part 32

As shown in FIG. 3, the wire holding part 32 has a ring shape as viewed from the length direction of the wire member 11. The wire holding part 32 encloses the outer periphery of the wire member 11. The wire member 11 is thereby held by the wire holding part 32.

The wire holding part 32 has, for example, a protruding part 32a that protrudes from the inner peripheral surface of the wire holding part 32. The protruding part 32a fits into the ring-shaped recessed part 25 of the exterior member 21, for example. The protruding part 32a thereby catches in the exterior member 21 of the wire member 11 in the length direction. Accordingly, relative positional shift between the exterior member 21 and the wire fixation member 12 in the length direction is suppressed.

The wire fixation member 12 of the present embodiment has a structure split into a first region 51 and a second region 52 from the wire holding part 32 to the fixation part 31, for example. The fixation part 31 is constituted by part of the first region 51 and part of the second region 52. The wire holding part 32 is constituted by part of the first region 51 and part of the second region 52.

The first region 51 and the second region 52 are joined to each other via a hinge part 53. The first region 51, the second region 52, and the hinge part 53 are, for example, formed integrally. The second region 52 is rotatable relative to the first region 51 about the hinge part 53 as the axis. The hinge part 53 is provided in, for example, the wire holding part 32.

The second region 52 has a locking part 55 that is locked by a lock part 54 provided in the first region 51. The first region 51 and the second region 52 are held in a closed state, by the locking part 55 being locked by the lock part 54. Note that the insertion hole 41 of the fixation part 31 is formed from the first region 51 to the second region 52 in the fixation part 31. Also, the elastic piece 42 of the fixation part 31 is, for example, part of the first region 51.

### Core Holding Part 33

As shown in FIGS. 1 and 4, the core holding part 33 includes a core holding part main body 61 formed integrally with the wire holding part 32 and a fastening member 71 that fastens and fixes the magnetic core 13 to the core holding part main body 61. The core holding part main body 61 holds a range from 90 degrees to 180 degrees inclusive of the magnetic core 13 in the circumferential direction thereof. The core holding part main body 61 of the present embodiment holds, for example, a range of approximately 120 degrees of the magnetic core 13 in the circumferential direction thereof. The magnetic core 13 held by the core holding part 33 opposes the wire holding part 32 in the length direction of the wire member 11.

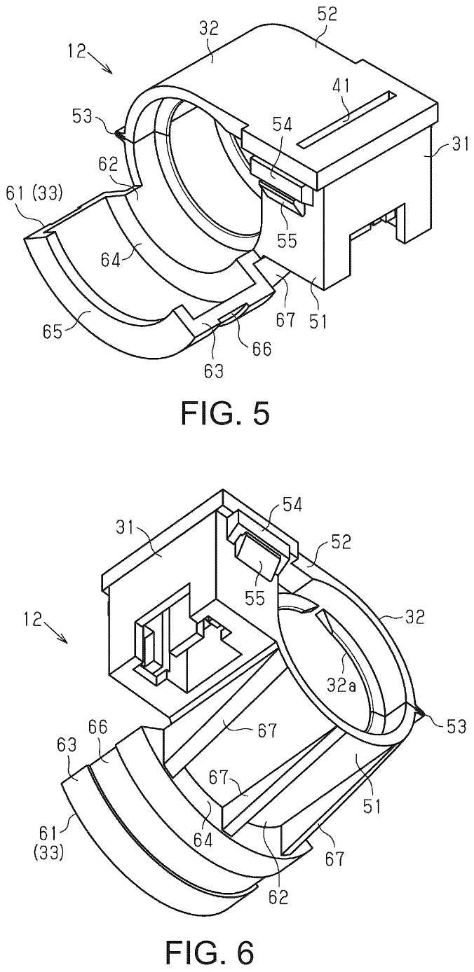

As shown in FIGS. 5 and 6, the core holding part main body 61 is joined to the wire holding part 32 via a coupling part 62. The core holding part main body 61 and the coupling part 62 are, for example, provided in the first region 51 forming the wire fixation member 12.

The core holding part main body 61 has a first holding part 63 that holds the outer peripheral surface of the magnetic core 13 and a pair of second holding parts 64 and 65 that hold both side surfaces of the magnetic core 13 in the length direction of the wire member 11. The first holding part 63 radially opposes the outer peripheral surface of the magnetic core 13. The pair of second holding parts 64 and 65 extend from both end portions of the first holding part 63 in the length direction of the wire member 11. The magnetic core 13 is disposed between the pair of second holding parts 64 and 65. The second holding parts 64 and 65 oppose the side surfaces of the magnetic core 13 in the length direction of the wire member 11. The magnetic core 13 is positioned in the length direction of the wire member 11 by the second holding parts 64 and 65. The coupling part 62 joins the second holding part 64 to the wire holding part 32. A positioning groove 66 for positioning the fastening member 71 in the length direction of the wire member 11 is provided on the outer peripheral surface of the first holding part 63.

As shown in FIG. 6, the coupling part 62 has a reinforcing rib 67. A plurality of reinforcing ribs 67 are provided, for example. The reinforcing ribs 67 are joined to the outer peripheral surface of the wire holding part 32 and to the second holding part 64 of the core holding part main body 61. The reinforcing ribs 67 improve the rigidity from the wire holding part 32 to the second holding part 64.

### Fastening Member 71

As shown in FIGS. 1 and 4, the fastening member 71 fastens the core holding part main body 61 and the magnetic core 13 together from the outer periphery. The fastening member 71 is a fastening band formed from, for example, synthetic resin. The fastening member 71 has a band-shaped part 72 and a lock part 73. The band-shaped part 72 is long and flexible. In the band-shaped part 72, a plurality of raised portions not shown are juxtaposed in the length direction of the band-shaped part 72.

The lock part 73 is provided integrally with a base end part of the band-shaped part 72 in the length direction thereof. The lock part 73 is locked by the raised portions of the band-shaped part 72 so as to restrict the movement of the band-shaped part 72 in a removal direction, which is the opposite direction to a passthrough direction in a state where the band-shaped part 72 is passed through the lock part 73. The band-shaped part 72 fastens the core holding part main body 61 and the magnetic core 13 together from the outer periphery, by being inserted into the lock part 73 from the distal end portion thereof and locked. That is, the band-shaped part 72 applies a force acting inwardly in the radial direction to the core holding part main body 61 and the magnetic core 13. The state in which the magnetic core 13 is located inside the core holding part main body 61 is thereby maintained.

The band-shaped part 72 of the fastening member 71 is disposed within the positioning groove 66 provided in the first holding part 63 of the core holding part main body 61. That is, positional shift of the band-shaped part 72 in the length direction of the wire member 11 is suppressed by the positioning groove 66.

The effects of the present embodiment will now be described.

(1) The wire holding part 32 and the core holding part 33 of the wire fixation member 12 are juxtaposed in the length direction of the wire member 11. According to this configuration, it becomes possible to suppress an increase in size of the wire fixation member 12 in the radial direction of the wire member 11, compared with a configuration in which the magnetic core 13 is disposed on the inner peripheral side of the wire holding part 32. Accordingly, it becomes possible to suppress an increase in size in the radial direction in the region where the magnetic core 13 is provided in the wiring harness 10.

(2) The core holding part 33 includes the core holding part main body 61 formed integrally with the wire holding part 32 and the fastening member 71 for fastening and fixing the magnetic core 13 to the core holding part main body 61. According to this configuration, it becomes possible to securely hold the magnetic core 13 with the core holding part main body 61 and the fastening member 71.

(3) The core holding part main body 61 holds a range from 90 degrees to 180 degrees inclusive of the magnetic core 13 in the circumferential direction thereof. According to this configuration, it becomes possible to stably hold the magnetic core 13 with the core holding part main body 61.

(4) The wire fixation member 12 includes the coupling part 62 that joins the wire holding part 32 to the core holding part 33. The coupling part 62 has the reinforcing ribs 67. According to this configuration, it becomes possible to improve the rigidity of the coupling part 62 joining the wire holding part 32 to the core holding part 33 in the wire fixation member 12 with the reinforcing ribs 67.

(5) The magnetic core 13 is formed in a ring shape by a single component. According to this configuration, the magnetic core 13 is constituted by a single component, thus contributing to improving the capacity of the magnetic core 13 to absorb electromagnetic noise.

### MODIFICATIONS

The present embodiment can be implemented in a modified manner as follows. The present embodiment and the following modifications can be implemented in combination with each other to the extent that no technical inconsistencies arise.
The magnetic core 13 of the above embodiment is formed in a ring shape by a single component, but the present disclosure is not particularly limited thereto, and the magnetic core 13 may be formed in a ring shape by combining a plurality of components.

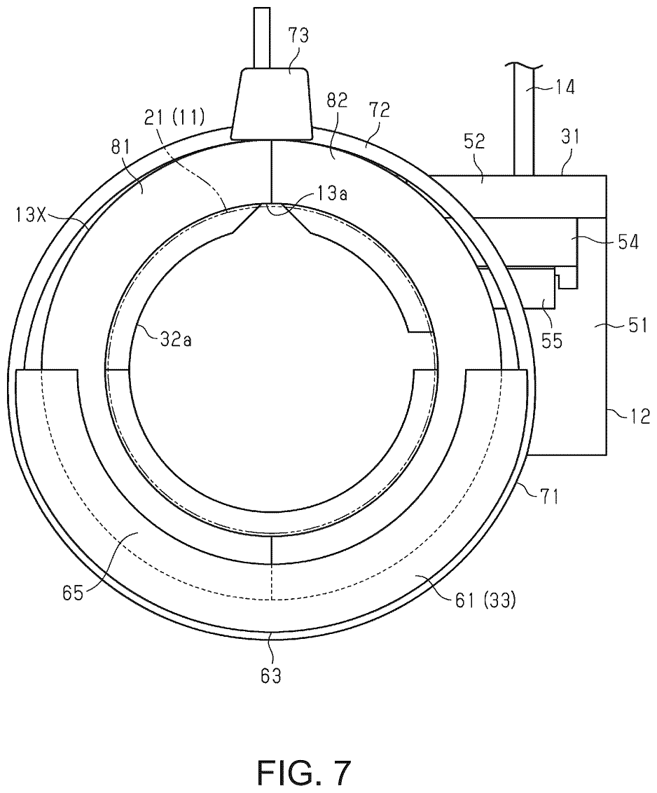

For example, a magnetic core 13X shown in FIG. 7 is formed in a ring shape by a plurality of components. The magnetic core 13X is, for example, formed in a ring shape by two components. The two components forming the magnetic core 13X are a first split core 81 and a second split core 82. The first split core 81 and the second split core 82 each have a shape obtained by the circular ring-shaped magnetic core 13X being divided in half. According to such a configuration, it becomes possible to assemble the magnetic core 13X from the outer peripheral side of the wire member 11. Accordingly, there are fewer constraints on the order in which the magnetic core 13X is assembled. Thus, it becomes possible to improve the operability with which the magnetic core 13X is assembled.

In the example shown in FIG. 7, the core holding part main body 61 of the wire fixation member 12 holds, for example, a range of approximately 180 degrees of the magnetic core 13X in the circumferential direction thereof. The core holding part main body 61 holds part of both the first split core 81 and the second split core 82 in the circumferential direction thereof. It thereby becomes possible to stably hold both the first split core 81 and the second split core 82 with the core holding part main body 61.
The number of reinforcing ribs 67 of the wire fixation member 12 is not limited to the above embodiment, and may be two or less or four or more.
The core holding part main body 61 of the wire fixation member 12 may be configured to hold a range of less than 90 degrees of the magnetic core 13 in the circumferential direction thereof.
The fastening member 71 may, for example, be an adhesive tape, apart from being a fastening band.
In the core holding part 33 of the above embodiment, the fastening member 71 may be omitted, and the magnetic core 13 may be held by only the core holding part main body 61. In this case, the core holding part main body 61 is preferably provided with a locking part such as a claw that holds the magnetic core 13.
Configuration such as the shape of the wire holding part 32 in the wire fixation member 12 is not limited to the above embodiment. For example, the wire holding part 32 may be an extension piece that extends in the length direction of the wire member 11, and the wire member 11 may be fixed to the extension piece by taping or the like.
In the wire fixation member 12, the fixation part 31 including the insertion hole 41 may be formed in only one of the first region 51 and the second region 52.
The exterior member 21 of the wire member 11 may, for example, be a pipe-shaped member having a uniform diameter in the length direction, apart from being a corrugated tube.
The wire member 11 may have one wire 22 or may have three or more wires 22.
The wires 22 of the wire member 11 may, for example, be unshielded wires not having their own electromagnetic shielding structure, or shielded wires having their own electromagnetic shielding structure. In the case where the wires 22 are shielded wires, the braided member 23 can be omitted.

The wiring harness 10 of the present embodiment shown in FIGS. 1 and 2 is, for example, provided in a vehicle such as a car. The wiring harness 10 includes the wire member 11, the wire fixation member 12, and the magnetic core 13. The wire fixation member 12 is a component that is fixed by the plate-shaped fixing part 14 provided in the vehicle.
The fixing part 14 with which the fixation part 31 of the wire fixation member 12 is fixed is not limited to the plate-shaped bracket of the above embodiment. For example, the fixing part 14 may be a through hole formed in a car body panel, and a fixation part of the wire fixation member 12 may be inserted into the through hole serving as the fixing part 14 and fixed.
As in the non-limiting embodiment shown in FIGS. 1 and 2, the ring-shaped magnetic core 13 may surround the outermost surface of the wiring harness 10, such as the outer peripheral surface of the tubular exterior member 21, for example, from the outer side in the radial direction.
As in the non-limiting embodiment shown in FIG. 5, the core holding part 33 can include a concave surface that is corresponded with a convex surface corresponding to part of the circumference of the outer peripheral surface of the ring-shaped magnetic core 13. The core holding part 33 may be configured to support the ring-shaped magnetic core 13 from below, for example.
As in the non-limiting embodiment shown in FIG. 5, for example, the wire fixation member 12 may have a step in the radial direction that depends on the thickness of the ring-shaped magnetic core 13 in the radial direction, between the core holding part 33 and the wire holding part 32. This step can function as a stopper surface for suppressing positional shift of the wire fixation member 12 in the length direction of the wire member 11, by coming in contact with the ring-shaped magnetic core 13.
The embodiments and modifications disclosed herein are to be considered in all respects as illustrative, and the present disclosure is not limited to these illustrative examples. That is, the scope of the present disclosure is indicated by the patent claims, and all changes that come within the meaning and range of equivalency of the patent claims are intended to be embraced therein.

1. A wiring harness comprising:
a wire member that includes:
an exterior tube; and
a wire that passes through an inside of the exterior tube;
a wire fixation member configured to fix the wire member with a fixing part; and
a ring-shaped magnetic core that surrounds an outer periphery of the exterior tube, wherein:
the wire fixation member includes
a fixation part that is fixed by the fixing part;
a wire holding part that holds the wire member; and
a core holding part that holds the magnetic core,
the wire holding part and the core holding part are juxtaposed in a length direction of the wire member, and
the core holding part includes
a circular arc-shaped core holding part main body formed integrally with the wire holding part; and
a fastening member that fastens the magnetic core and the circular arc-shaped core holding part main body together from an outer periphery, by being wrapped around an outer peripheral surface of the magnetic core and an outer peripheral surface of the circular arc-shaped core holding part main body.

2. The wiring harness of claim 1,
wherein the core holding part main body holds a range from 90 degrees to 180 degrees inclusive of the magnetic core in a circumferential direction thereof.

3. The wiring harness of claim 1, wherein:
the wire fixation member has a coupling part joining the wire holding part to the core holding part, and
the coupling part has a reinforcing rib.

4. The wiring harness of claim 1,
wherein the magnetic core is formed in a ring shape by a single component.

5. The wiring harness of claim 1,
wherein the magnetic core is formed in a ring shape by a plurality of components.

6. A wire fixation member configured to fix a wire member having an exterior tube and a wire passing through an inside of the exterior tube with a fixing part, comprising:
a fixation part that is fixed by the fixing part;
a wire holding part that holds the wire member; and
a core holding part that holds a ring-shaped magnetic core surrounding an outer periphery of the exterior tube, wherein:
the wire holding part and the core holding part are juxtaposed in a length direction of the wire member, and
the core holding part includes
a circular arc-shaped core holding part main body formed integrally with the wire holding part; and
a fastening member that fastens the magnetic core and the circular arc-shaped core holding part main body together from an outer periphery, by being wrapped around an outer peripheral surface of the magnetic core and an outer peripheral surface of the circular arc-shaped core holding part main body.

7. (canceled)
